(19) United States
(12) Patent Application Publication
(10) Pub. No.: US 2026/0173761 A1
(43) Pub. Date: Jun. 18, 2026

(54) PROCESS FOR MANUFACTURING A PIEZOELECTRIC LAYER ON A SUBSTRATE

(71) Applicant: Soitec, BERNIN (FR)

(72) Inventors: Ludovic Ecarnot, BERNIN (FR); Bich-Yen Nguyen, BERNIN (FR); Christophe Maleville, BERNIN (FR); Ionut Radu, BERNIN (FR); Walter Schwarzenbach, BERNIN (FR)

(21) Appl. No.: 19/122,351

(22) PCT Filed: Oct. 20, 2023
(86) PCT No.: PCT/FR2023/051650

§ 371 Date: Apr. 18, 2025

(30) Foreign Application Priority Data
Oct. 20, 2022 (FR) FR2210858

(51) Int. Cl. H10N 30/079; H03H 9/02; H03H 9/64; H10N 30/00

(52) U.S. Cl. CPC H10N 30/079; H03H 9/02968; H03H 9/64; H10N 30/708

(57) ABSTRACT

A method of manufacturing a structure including a piezoelectric layer on a substrate involves:—forming, by a first epitaxy, a pseudomorphic seed layer of a first piezoelectric material on a donor substrate,—transferring the seed layer and a portion of the donor substrate onto a receiver substrate via at least one electrically insulating layer and/or at least one electrically conductive layer adapted to allow relaxation of the seed layer,—removing the transferred portion of the donor substrate so as to expose a surface of the seed layer,—and forming a monocrystalline layer of a second piezoelectric material on the seed layer.

### CROSS-REFERENCE TO RELATED APPLICATIONS

This application is a national phase entry under 35 U.S.C. § 371 of International Patent Application PCT/FR 2023/051650, filed Oct. 20, 2023, designating the United States of America and published as International Patent Publication WO 2024/084179 A1 on Apr. 25, 2024, which claims the benefit under Article 8 of the Patent Cooperation Treaty of French Patent Application Serial No. FR 2210858, filed Oct. 20, 2022.

### TECHNICAL FIELD

The present disclosure relates to a process for manufacturing a piezoelectric layer on a substrate.

### BACKGROUND

Various acoustic components are used for filtering in the radiofrequency domain, including surface acoustic wave (SAW for short) filters, which typically comprise a thick piezoelectric layer (i.e., generally, several tens of nm to several tens of um thick) and two electrodes in the form of two interdigitated metal combs deposited on the surface of the piezoelectric layer. An electrical signal, typically an electric voltage variation, applied to an electrode is converted into an elastic wave that propagates on the surface of the piezoelectric layer. The propagation of this elastic wave is favored if the frequency of the wave corresponds to the frequency band of the filter. This wave is again converted into an electrical signal when it reaches the other electrode. The piezoelectric layer must have excellent crystalline quality to avoid attenuating the surface wave. Therefore, using a monocrystalline layer here is preferred. At present, suitable materials for industrial use are quartz, LiNbO₃ or LiTaO₃.

Currently, the piezoelectric layer is obtained by cutting an ingot of one of the materials, which results in low precision for the thickness of the layer as well as a non-uniform thickness over the entire layer.

In addition, the diameters of the ingots of piezoelectric materials are smaller than the diameters of the ingots of materials used for the substrate, such as silicon. However, to achieve direct transfer, in particular, SMART CUT™-type layer transfer, it is necessary for the donor and receiver substrates to be of the same diameter.

There is still a need for processes that can form a uniform, high-quality thick piezoelectric layer on a large-diameter substrate.

### BRIEF SUMMARY

One aim of the present disclosure is to design a process for manufacturing a substrate for a microelectronic, photonic or optical device, including but not limited to a surface acoustic wave device, in particular, by making it possible to obtain thick (i.e., thickness greater than 5 μm, or even greater than 15 μm), uniform, high-quality layers of large diameter (i.e., diameter greater than 15 or 20 cm).

In accordance with the present disclosure, a process is proposed for manufacturing a piezoelectric layer on a substrate, characterized in that the process comprises;
forming, by a first epitaxy, a seed layer of a first piezoelectric material on a donor substrate,
transferring the seed layer and a portion of the donor substrate to a receiver substrate via at least one electrically insulating layer and/or at least one electrically conductive layer adapted to allow relaxation of the seed layer,
removing the transferred portion of the donor substrate so as to expose a surface of the seed layer, and
forming a monocrystalline layer of a second piezoelectric material on the seed layer.

According to a first embodiment, the transferring of the seed layer and portion of the donor substrate comprises the following steps:
forming an embrittlement area in the donor substrate to delimit the portion to be transferred,
bonding the donor substrate to the receiver substrate, with the seed layer at the bonding interface, and
detaching the donor substrate along the embrittlement area, and the formation of the seed layer on the donor substrate takes place prior to the formation of the embrittlement area.

According to a second embodiment, the transferring of the seed layer and portion of the donor substrate comprises the following steps:
forming an embrittlement area in the donor substrate to delimit the portion to be transferred,
bonding the donor substrate to the receiver substrate, with the seed layer at the bonding interface, and
detaching the donor substrate along the embrittlement area, and the formation of the seed layer on the donor substrate takes place after the formation of the embrittlement area.

The embrittlement area can be formed by ion implantation, in particular, of hydrogen and/or helium, into the donor substrate.

Preferably, the seed layer is formed on the donor substrate by atomic layer deposition. Alternatively, the seed layer is formed on the donor substrate by molecular beam epitaxy.

Preferably, the monocrystalline layer of the second piezoelectric material is formed by a second epitaxy.

Preferably, the second epitaxy of the second piezoelectric material on the seed layer is an organometallic chemical vapor deposition.

Alternatively, the formation of the monocrystalline layer on the seed layer is achieved by depositing the second piezoelectric material in amorphous form, followed by recrystallizing the second material.

Advantageously, the thickness of the seed layer is between 2 nm and 20 nm.

Advantageously, the portion of the donor substrate transferred to the receiver substrate has a thickness of less than 2 μm, preferably less than 1 μm.

Advantageously, the thickness of the layer of second piezoelectric material after the second epitaxy is between 20 nm and 15 μm.

In a particular embodiment, the process comprises, after forming the monocrystalline layer of the second piezoelectric material, transferring at least part of the layer of the second piezoelectric material to a final substrate.

Advantageously, the portion of the layer of second piezoelectric material transferred to the final substrate has a thickness of less than 2 μm, preferably less than 1 μm.

The receiver substrate or final substrate may comprise at least one electronic device or interconnect.

The receiver substrate or final substrate may comprise a trap-rich layer.

The first piezoelectric material and the second piezoelectric material can be identical. Alternatively, the first piezoelectric material and the second piezoelectric material can be different.

In one embodiment, an intermediate layer suitable for epitaxial growth of the seed layer on the donor substrate can be formed on the donor substrate prior to the formation of the seed layer.

Another object relates to a process for manufacturing a surface acoustic wave device, comprising the formation of two interdigitated electrodes on the surface of a piezoelectric layer, characterized in that it comprises manufacturing the piezoelectric layer by a process as described above.

A further object relates to a process for manufacturing a photonic device, comprising forming at least one photonic component, such as a laser or a light-emitting diode, at least partly in a piezoelectric layer, characterized in that it comprises manufacturing the piezoelectric layer by a process as described above.

A further object relates to a surface acoustic wave device, characterized in that it comprises a piezoelectric layer obtainable by a process as described above, and two interdigitated electrodes on one face of the piezoelectric layer.

Another object concerns a photonic device, characterized in that it comprises a piezoelectric layer obtainable by a process as described above, and at least one photonic component, such as a laser, modulator, waveguide or multiplexer, formed at least partially in the piezoelectric layer.

The present disclosure further relates to a structure comprising at least one such surface acoustic wave device and one such photonic device, comprising a single piezoelectric layer wherein the surface acoustic wave device and the photonic device are arranged.

### BRIEF DESCRIPTION OF THE DRAWINGS

Other features and advantages of the present disclosure will emerge from the following detailed description with reference to the appended drawings, wherein:

FIG. 1 is a schematic cross-section of a surface acoustic wave filter;

FIGS. 2A and 2B illustrate two successive first steps in a process for manufacturing a monocrystalline piezoelectric layer according to a first embodiment of the present disclosure;

FIGS. 3A and 3B illustrate two successive first steps of the process according to a second embodiment of the present disclosure;

FIGS. 4 to 8 illustrate successive steps of the process according to the first or second embodiment of the present disclosure; and

FIGS. 9 to 11 illustrate optional further steps of the process.

For the sake of the legibility of the figures, some elements are not necessarily drawn to scale. Furthermore, the elements designated by the same reference signs in different figures are identical.

### DETAILED DESCRIPTION

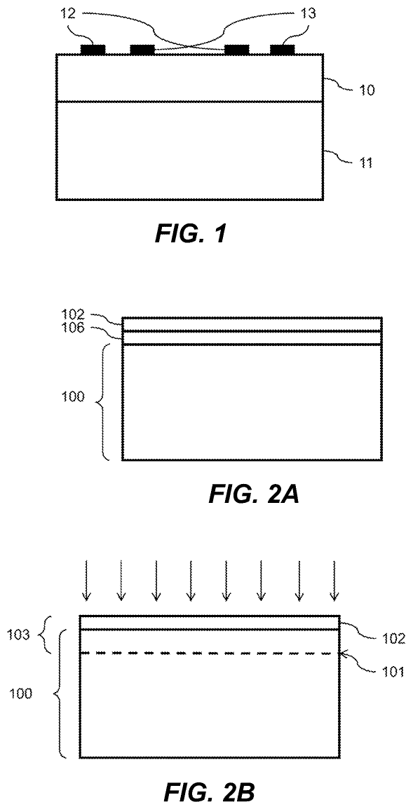

FIG. 1 is a schematic view of a surface acoustic wave filter.

The filter comprises a piezoelectric layer 10 and two electrodes 12, 13 in the form of two interdigitated metal combs deposited on the surface of the piezoelectric layer. On the side opposite the electrodes 12, 13, the piezoelectric layer rests on a substrate 11. The piezoelectric layer 10 is monocrystalline, as excellent crystalline quality is preferable to avoid attenuating the surface wave.

Generally speaking, the present disclosure proposes the formation of a monocrystalline piezoelectric layer by way of a transfer of an epitaxially grown seed layer of a first piezoelectric material onto a donor substrate, the transfer being carried out from the donor substrate to a receiver substrate. Next, a layer of a second piezoelectric material is formed on the seed layer to achieve the desired thickness of the monocrystalline layer of the second piezoelectric material.

The donor substrate can be a monocrystalline bulk substrate of the first piezoelectric material or of another material. Alternatively, the donor substrate can be a composite substrate, i.e., formed from a stack of at least two layers of different materials, one surface layer of which consists of the first monocrystalline piezoelectric material or another monocrystalline material. The monocrystalline material is suitable for epitaxial growth of the seed layer; in particular, it has a lattice parameter sufficiently close to the lattice parameter of the seed layer so as not to generate crystalline defects during the growth of the seed layer.

Particularly advantageously, the seed layer is pseudomorphic, i.e., the actual lattice parameter of the seed layer material is forced, for example, by atomic forces, to substantially match the lattice parameter of the donor substrate on which it is formed. To this end, the thickness of the seed layer must not exceed a critical thickness, beyond which stress relaxation and defect generation would occur in the seed layer. This critical thickness depends on the material of the seed layer. For example, the critical thickness is typically less than 5 nm for a germanium seed layer formed on a silicon substrate. Generally, the critical thickness is between 2 nm and 20 nm, depending on the materials chosen for the seed layer and substrate.

In some embodiments, an intermediate layer (known as an “epitaxial intermediate layer”) of a material suitable for growing the seed layer on the donor substrate can be formed on the donor substrate prior to the formation of the seed layer. The usefulness of such an intermediate layer depends, in particular, on the chemical stability between the seed layer and the donor substrate. Thus, if the growth of the seed layer directly on the donor substrate is not hindered by interactions or chemical reactions between the seed layer material and that of the donor substrate, there is no need for an intermediate layer. On the other hand, if chemical interactions or reactions between the seed layer material and the donor substrate material are likely to prevent the growth of the seed layer, it is desirable to use an intermediate layer made of a material that is stable with respect to the donor substrate material and the seed layer material. For example, a monocrystalline germanium layer can be formed on a silicon donor substrate to promote the growth of the seed layer of the first piezoelectric material. In other embodiments, the intermediate layer can be made of monocrystalline strontium titanate (SrTiO₃), monocrystalline aluminum oxide (AI₂O₃), monocrystalline lanthanum aluminate (LaAIO₃), or a monocrystalline metal such as aluminum.

The receiver substrate acts as a mechanical support for the seed layer. It can be of any type suitable for epitaxy (particularly in terms of temperature resistance) and, advantageously but not necessarily, suitable for the intended application. It can be solid or composite. Advantageously, the receiver substrate may comprise at least one electronic device or interconnect.

At least one intermediate layer (known as the “relaxation intermediate layer”) is sandwiched between the receiver substrate and the seed layer. For example, such an intermediate layer can be electrically conductive or electrically insulating. The person skilled in the art will be able to choose the material and thickness of this layer according to the properties they wish to confer on the radio-frequency device intended to comprise the piezoelectric layer. This intermediate layer allows the seed layer to relax freely. The transferred pseudomorphic seed layer can thus freely regain its lattice parameter during the transfer, or between the transfer and the formation of the second layer of the second piezoelectric material, or during the formation of the second layer of the second piezoelectric material.

The material of the intermediate layer may advantageously be selected from silicon oxide (SiO₂), a nitride or a metal.

The intermediate layer can be formed on the donor substrate (on the seed layer) or on the receiver substrate.

An intermediate layer made of silicon oxide can be deposited or obtained by thermal oxidation. The technique for forming the layer is chosen, in particular, as a function of the substrate on which it is to be formed and any limits (e.g., thermal) to be complied with. For example, if the intermediate layer is formed on the receiver substrate and the latter contains electronic components, a technique with a thermal budget that does not risk damaging the components will be chosen.

Advantageously, the receiver substrate can be made of a semi-conductive material. This may be, for example, a silicon substrate.

In some embodiments, in particular, when the receiver substrate is the final support for the piezoelectric layer, the receiver substrate comprises a trap-rich layer, which can either be formed on the receiver substrate, or formed in a surface region of the receiver substrate. The trap-rich layer is thus located between the seed layer and the receiver substrate and improves the electrical insulation performance of the receiver substrate. The trap-rich layer can be formed by at least one polycrystalline, amorphous or porous semiconductor material, in particular, but not limited to, polycrystalline silicon, amorphous silicon, or porous silicon. Furthermore, depending on the temperature resistance of the trap-rich layer for epitaxy, it may be advantageous to introduce an additional layer between the receiver substrate and the trap-rich layer, in order to avoid recrystallization of the latter during heat treatment.

The seed layer has a negligible thickness compared with the thickness of the final monocrystalline piezoelectric layer. As a result, it is considered to have no significant influence on the operation of the radio-frequency device incorporating the monocrystalline piezoelectric layer.

The seed layer typically has a thickness between 1 and 20 nm.

The thickness of the layer of second piezoelectric material formed on the seed layer depends on the specifications of the device intended to incorporate the monocrystalline piezoelectric layer. In this respect, the thickness of the layer formed on the seed layer is not limited in terms either of minimum or maximum value. The thickness of the final piezoelectric layer is typically between 20 nm and 15 μm.

The first piezoelectric material is advantageously selected from a compound of formula ABO₃, where A is selected from barium and lithium and B is selected from titanium and niobium. However, the interest in these materials is not limited to their piezoelectric properties. In particular, for other applications, such as integrated optics, they may also be of interest for their dielectric permittivity, refractive indices, or pyroelectric, ferroelectric, or ferromagnetic properties, for example.

The first epitaxy can be performed using any technique suitable for achieving high crystal quality, such as atomic layer deposition (ALD) or molecular beam epitaxy (MBE). These techniques are characterized by very low growth rates. However, as the seed layer has a low thickness, using one of these techniques to grow the seed layer has a low economic impact on the process, but does achieve a crystalline quality in the seed layer that will promote the crystalline quality of the monocrystalline layer of the second piezoelectric material.

According to a first alternative, the layer of second piezoelectric material can be formed on the seed layer by a second epitaxy.

The second epitaxy can be performed using any technique offering a higher growth rate than the first, in particular, metal organic chemical vapor deposition (MOCVD). Although it provides lower crystal quality than ALD or MBE techniques, this second epitaxy is more economical for growing a relatively thick monocrystalline layer.

According to a second alternative, the layer of second piezoelectric material can be formed by deposition of the piezoelectric material in amorphous form, followed by recrystallizing the material to give it a monocrystalline structure. Alternatively, the process can be carried out in several successive cycles, each comprising the depositing of the amorphous piezoelectric material over a certain thickness, followed by recrystallizing the material over the thickness, until the desired total thickness of the layer of second piezoelectric material is obtained.

The amorphous material can be deposited by any technique known to the skilled worker, and advantageously by MOCVD, Low-Pressure Chemical Vapor Deposition (LPCVD), Plasma-Enhanced Chemical Vapor Deposition (PECVD), or sputtering.

The person skilled in the art will be able to determine the reagents and operating conditions depending on the piezoelectric material to be grown and the technique chosen.

Transferring the seed layer typically involves a step of bonding the donor substrate to the receiver substrate, with the seed layer and intermediate relaxation layer at the bonding interface, followed by a step of thinning the receiver substrate to expose the seed layer for subsequent epitaxy.

The bonding step can be carried out, for example, by direct molecular bonding known as wafer bonding, with or without an additional intermediate layer.

Particularly advantageously, the transfer is performed using the SMART CUT™ process, which is well-known for transferring semiconductor thin films, particularly silicon.

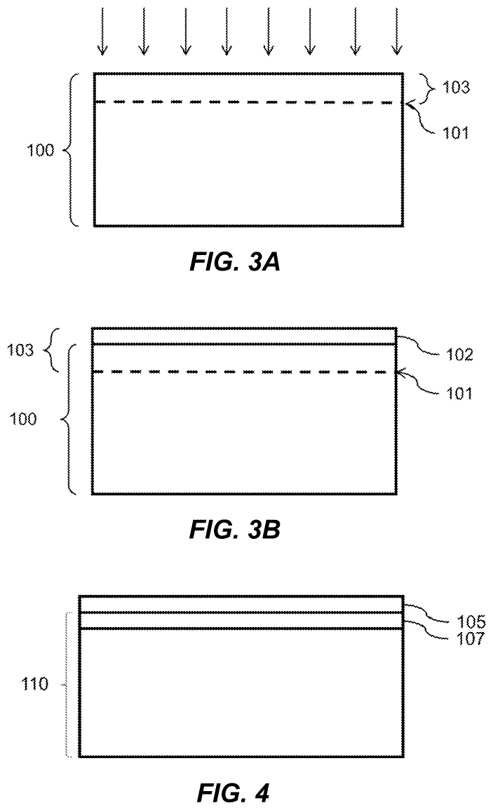

To this end, with reference to FIG. 2A, according to a first embodiment, a donor substrate 100 is provided and a layer of a first monocrystalline piezoelectric material, called a seed layer 102, is grown by a first epitaxy. The first piezoelectric material has a lattice parameter close to that of the donor substrate. In this way, the donor substrate 100 imposes its lattice parameter and enables the growth of a good-quality monocrystalline material. Growth is stopped when the desired thickness of the seed layer is reached. In this figure, the donor substrate 100 is shown as solid but, as indicated above, it could also be composite.

Advantageously but optionally, an intermediate epitaxy layer 106 can be formed on the donor substrate 100 prior to the epitaxy of the seed layer 102. For the sake of simplicity, the layer 106 has not been shown in the following figures.

Referring to FIG. 2B, an embrittlement area 101 is formed by ion implantation (shown by the arrows) through the seed layer into the donor substrate, delimiting a monocrystalline layer 103 to be transferred, comprising the seed layer and a portion of the donor substrate. Advantageously, and depending on the piezoelectric material in question, the implanted species are hydrogen or helium, alone or in combination. The person skilled in the art will be able to determine the dose and implantation energy of these species to form the embrittlement area at a given depth, which is preferably between 0.2 μm and 0.6 μm; typically, and again depending on the piezoelectric material and implanted species considered, the dose is in the range of 2 E+16 to 2 E+17 ionic species/cm², and the implantation energy is from 30 keV to 500 keV. The buried embrittled layer can also be obtained by any other means known to the skilled worker, for example, by porosification of the material, or by laser irradiation. However, as explained below, there are transfer processes that do not require ion implantation, and the present disclosure can be implemented with these processes.

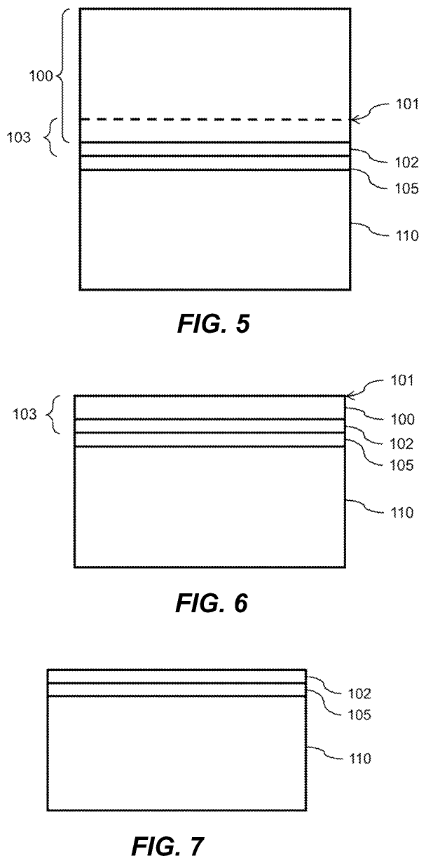

FIGS. 3A and 3B illustrate a second embodiment of the process for manufacturing a monocrystalline piezoelectric layer. The second embodiment is an alternative to the first embodiment, shown in FIGS. 2A and 2B, wherein implantation in the donor substrate is carried out prior to the seed layer being formed by a first epitaxy.

Referring to FIG. 3A, a donor substrate 100 is provided and, by ion implantation (shown by the arrows) into the donor substrate 100, an embrittlement area 101 is formed, delimiting a monocrystalline layer 103 to be transferred.

Referring to FIG. 3B, a layer of a first monocrystalline piezoelectric material, called the seed layer 102, is grown on the layer 103 to be transferred by way of a first epitaxy. As previously mentioned, the donor substrate 100 imposes its lattice parameter and enables the growth of a good-quality monocrystalline material. The first piezoelectric material has a lattice parameter close to that of the donor substrate. Growth is stopped when the desired thickness of the seed layer is reached. In this figure, the donor substrate 100 is shown as solid but, as indicated above, it could also be composite.

Advantageously, the thermal budget of the first epitaxy is lower than the thermal budget likely to cause the donor substrate to fracture along the embrittlement area. In this way, the donor substrate retains its mechanical cohesion until the growth of the seed layer is complete.

After the steps shown in FIGS. 2A and 2B or 3A and 3B, a seed layer 102 is obtained on the donor substrate 100 wherein an embrittlement area has been formed by implantation and which defines a layer 103 to be transferred that comprises the seed layer 102.

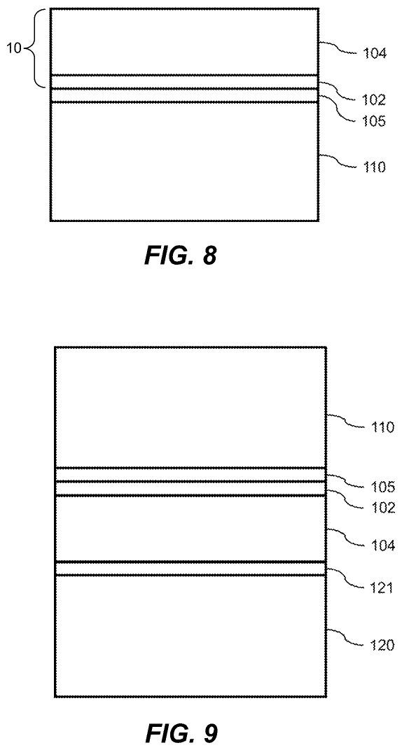

Referring to FIG. 4, at least one electrically insulating or electrically conductive intermediate relaxation layer 105 is formed on the surface of the receiver substrate 110. The receiver substrate 110 may further comprise a trap-rich layer 107. For the sake of simplicity, the layer 107 has not been shown in the following figures.

Referring to FIG. 5, the donor substrate 100 thus embrittled is bonded to the receiver substrate 110, with the seed layer 102 and the intermediate relaxation layer 105 at the bonding interface.

Referring to FIG. 6, the donor substrate 100 is detached along the embrittlement area 101. Such detachment can be brought about by any means known to the person skilled in the art, e.g., thermal, mechanical, chemical, etc. The layer 103 is then transferred to the receiver substrate 110. Advantageously, the remainder of the donor substrate can then be recovered for recycling.

Referring to FIG. 7, a surface portion of the transferred layer is removed, for example, by mechanical polishing and/or chemical etching. The purpose of this material removal is to expose the seed layer 102. The result of removal is a thinned seed layer 102 on the receiver substrate 110, which will serve as the seed layer for the next step.

Referring to FIG. 8, a layer of a second piezoelectric material 104 is formed on the seed layer 102. The material of layer 104 has a lattice parameter close to or identical to that of the seed layer 102. In this way, the seed layer 102 imposes its lattice parameter and enables the growth of a good-quality monocrystalline material. The layer 104 may be slightly different in nature from the seed layer 102, in particular, through the controlled introduction of slight levels of impurities for various purposes (doping, adjustment of piezoelectric properties, optimization of crystalline defect/dislocation densities, surfactant, etc.). Growth is stopped when the desired thickness of the monocrystalline piezoelectric layer is reached. The final piezoelectric layer 10 is formed by stacking the seed layer 102 and the layer 104.

The first piezoelectric material and the second piezoelectric material can be identical.

Alternatively, the first piezoelectric material and the second piezoelectric material can be different.

As mentioned above, the seed layer is considered to have no effect or a second-order effect on the operation of a radio-frequency device incorporating the piezoelectric layer formed on the seed layer. Consequently, even if the implantation carried out for the implementation of the SMART CUT198 process damages the seed layer and disturbs its piezoelectric properties, these defects are of little or no penalty.

In a non-illustrated embodiment, no embrittlement area is formed in the donor substrate. In this case, the transfer of the seed layer to the receiver substrate is achieved by joining the donor substrate to the receiver substrate and then etching the donor substrate until the seed layer is exposed. However, this process is less preferred than the one comprising the formation of an embrittlement area in the donor substrate, as it results in greater material loss.

In a further embodiment not shown, no embrittlement area is formed in the donor substrate, but a detachable interface is formed by chemical or thermal reaction. In this case, the transfer of the seed layer to the receiver substrate is achieved by joining the donor substrate to the receiver substrate and then detaching the interface after a chemical or thermal reaction to expose the seed layer.

As shown in FIG. 8, the process results in a substrate for a surface acoustic wave device, comprising a receiver substrate 110 and a monocrystalline piezoelectric layer 10 on the receiver substrate 110. Such a substrate may also prove useful for other applications, such as photonics and integrated optics.

The piezoelectric layer 10 is characterized by the presence of two portions with different characteristics:
a first portion 102 located at the interface with the receiver substrate 110, corresponding to the seed layer, and
a second portion 104 extending from the first portion 102, corresponding to the layer formed on the first portion 102, which may have a crystalline quality different from that of the first portion (the quality may be adjusted and optimized during the second epitaxy step, for example) and/or a different composition (particularly if impurities, such as dopants, have been introduced during epitaxy), possibly conferring special properties on the layer formed on the first portion 102.

This substrate is advantageously used to manufacture a surface acoustic wave device as shown in FIG. 1 and/or any other microelectronic, photonic or optical device comprising a piezoelectric layer.

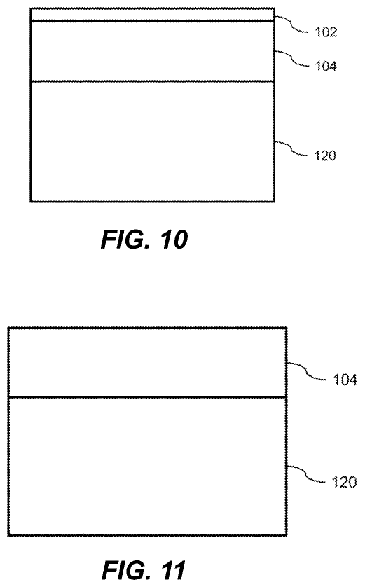

In some cases, the receiver substrate to which the seed coat is transferred may not be optimal for the intended application. In some embodiments, since the receiver substrate must undergo the epitaxy operating conditions, the choice of suitable materials is limited. In particular, the receiver substrate cannot contain layers or elements that could be damaged by the epitaxy temperature. It may then be advantageous to transfer the piezoelectric layer 10 onto a final substrate 120 whose properties are chosen according to the intended application, by bonding it to said the final substrate 120 via the surface of the layer 104 formed on the seed layer 102 (see FIG. 9), and removing the receiver substrate (see FIG. 10). This transfer can be carried out using any of the transfer techniques mentioned above. A further advantage of this transfer to a final substrate is that the seed layer 102, which was buried in the structure created by the formation of the layer of second piezoelectric material, is now exposed and can be removed if necessary (see FIG. 11), particularly if it has defects. Only the layer of second portion 104 then remains on the final substrate 120.

The final substrate can be solid or composite.

Advantageously, the final substrate may comprise at least one electronic device or interconnect.

In some embodiments, the final substrate comprises a trap-rich layer (designated 121 in FIG. 9), which can either be formed on the final substrate, or formed in a surface region of the final substrate. The trap-rich layer is thus located between the piezoelectric layer and the final substrate, improving the electrical insulation performance of the final substrate. The trap-rich layer can be formed by at least one polycrystalline, amorphous or porous semiconductor material, in particular, but not limited to, polycrystalline silicon, amorphous silicon, or porous silicon.

In the case of a surface acoustic wave device, metal electrodes 12, 13 in the form of two interdigitated combs are deposited on the surface of the piezoelectric layer 10 opposite the receiver substrate or, as the case may be, the final substrate (whether the receiver substrate 110 or the final substrate 120, the substrate forms the support substrate 11 shown in FIG. 1).

In other applications, at least one photonic component, such as a laser, modulator, waveguide, or multiplexer, can be formed in the piezoelectric layer, or in a stack of layers comprising the piezoelectric layer.

Particularly advantageously, it is possible to integrate a surface acoustic wave device and a photonic device in the same substrate. To this end, at least one surface acoustic wave device and one photonic device, such as a laser, modulator, waveguide or multiplexer, are formed in the same piezoelectric layer. It is also possible to combine these devices as described with other devices present in the receiver substrate or the final substrate, thus aiming at known 2D, 2.5D and 3D device co-integration approaches.

1. A method of manufacturing a structure including a piezoelectric layer on a substrate, comprising:
forming, by a first epitaxy, a seed layer of a first piezoelectric material on a donor substrate;
transferring the seed layer and a portion of the donor substrate to a receiver substrate via at least one electrically insulating layer and/or at least one electrically conductive layer adapted to allow relaxation of the seed layer;
removing the transferred portion of the donor substrate so as to expose a surface of the seed layer; and
forming a monocrystalline layer of a second piezoelectric material on the seed layer.

2. The method of claim 1, wherein the transferring the seed layer and the portion of the donor substrate comprises the following steps:
forming an embrittlement area in the donor substrate to delimit the portion to be transferred;
bonding the donor substrate to the receiver substrate, with the seed layer at the bonding interface; and
detaching the donor substrate along the embrittlement area; and wherein the forming, by the first epitaxy, the seed layer takes place after the forming the embrittlement area.

3. The method of claim 1, wherein the transferring of the seed layer and the portion of the donor substrate comprises the following steps:
forming an embrittlement area in the donor substrate to delimit the portion to be transferred;
bonding the donor substrate to the receiver substrate, with the seed layer at the bonding interface; and
detaching the donor substrate along the embrittlement area; and wherein the forming, by the first epitaxy, the seed layer on the donor substrate takes place prior to the forming the embrittlement area.

4. The method of claim 2, wherein the embrittlement area is formed by ion implantation of hydrogen and/or helium into the donor substrate.

5. The method of claim 1, wherein the forming the seed layer on the donor substrate is carried out by atomic layer deposition.

6. The method of claim 1, wherein the forming the seed layer on the donor substrate is carried out by molecular beam epitaxy.

7. The method of claim 1, wherein the forming the monocrystalline layer on the seed layer is carried out by a second epitaxy.

8. The method of claim 7, wherein the second epitaxy of the second piezoelectric material on the seed layer comprises an organometallic chemical vapor deposition.

9. The method of claim 1, wherein the formation of the monocrystalline layer on the seed layer is achieved by deposition of the second piezoelectric material in amorphous form, followed by recrystallization of the second piezoelectric material.

10. The method of claim 1, wherein a thickness of the seed layer is between 2 nm and 20 nm.

11. The method of claim 1, wherein the portion of the donor substrate transferred to the receiver substrate has a thickness of less than 2 μm.

12. The method of claim 1, wherein a thickness of the monocrystalline layer of second piezoelectric material is between 20 nm and 15 μm an end of the second epitaxy.

13. The method of claim 1, wherein the receiver substrate comprises at least one electronic device or interconnect.

14. The method of claim 1, wherein the receiver substrate comprises a trap-rich layer.

15. The method of claim 1, further comprising, after formation of the monocrystalline layer of the second piezoelectric material, transferring at least part of the layer of the second piezoelectric material onto a final substrate.

16. The method of claim 15, wherein the portion of the layer of the second piezoelectric material transferred onto the final substrate has a thickness of less than 2 μm.

17. The method of claim 15, wherein the final substrate comprises at least one electronic device or interconnect.

18. The method of claim 15, wherein the final substrate comprises a trap-rich layer.

19. The method of claim 1, wherein the first piezoelectric material and the second piezoelectric material are identical.

20. The method of claim 1, wherein the first piezoelectric material and the second piezoelectric material are different.

21. The method of claim 1, further comprising, prior to the forming the seed layer the forming an intermediate layer on the donor substrate, the intermediate layer being adapted for the epitaxial growth of the seed layer on the donor substrate.

22. A method of manufacturing a surface acoustic wave device, comprising:
manufacturing a structure including a piezoelectric layer on a substrate according to claim 1; and
forming two interdigitated electrodes on the surface of the piezoelectric layer.

23. A method of manufacturing a photonic device, comprising:
manufacturing a structure including a piezoelectric layer on a substrate according to claim 1; and
forming at least one photonic component at least partly in the piezoelectric layer.

24. A surface acoustic wave device, comprising a piezoelectric layer formed in accordance with the method of claim 1, and two interdigitated electrodes on one side of the piezoelectric layer.

25. A photonic device, comprising a piezoelectric layer formed in accordance with the method of claim 1, and at least one photonic component formed at least partially in the piezoelectric layer.

26. A structure, comprising:
a surface acoustic wave device comprising a piezoelectric layer formed in accordance with the method of claim 1, and two interdigitated electrodes on one side of the piezoelectric layer; and
a photonic device comprising at least one photonic component formed at least partially in the piezoelectric layer.
